(19) United States
(12) Patent Application Publication
(10) Pub. No.: US 2012/0305968 A1
(43) Pub. Date: Dec. 6, 2012

(54) LIGHT EMITTING DEVICE

(75) Inventor: Hideo Iwase, Kawasaki-shi (JP)

(73) Assignee: CANON KABUSHIKI KAISHA, Tokyo (JP)

(21) Appl. No.: 13/484,178

(22) Filed: May 30, 2012

(30) Foreign Application Priority Data
Jun. 6, 2011 (JP) 2011-126780

(51) Int. Cl. H01L 33/60

(52) U.S. Cl. 257/98; 257/E33.073

(57) ABSTRACT

Provided is a light emitting device that can suppress variation in a resonance frequency of a mode, so that light emission can be enhanced at high efficiency even in a case where photonic crystal, in which defect cavities are periodically arranged, is used. The light emitting device includes: an active layer; a photonic crystal layer including defects introduced therein, the defects disturbing periodicity of a refractive index distribution of photonic crystal; and a cladding layer having a refractive index lower than an effective refractive index of the photonic crystal layer, in which the defects are used as defect cavities. The photonic crystal layer has a structure in which the defect cavities are arranged. Each of the defect cavities has a major axis and a minor axis having different axial lengths, and the major axes are directed in different directions between neighboring defect cavities.

### BACKGROUND OF THE INVENTION

1. Field of the Invention

The present invention relates to a light emitting device, and more particularly, to a light emitting device having improved luminance by using photonic crystal in which defect cavities are formed.

2. Description of the Related Art

In recent years, many studies have been conducted for improving luminance of a light emitting device by using a cavity of photonic crystal.

If an active layer is placed in an electric field enclosed in a cavity to increase its intensity, coupling between the electric field and the active layer is enhanced so that a spontaneous emission rate of the active layer is increased.

If the spontaneous emission rate rises, carriers that are in nonradiative recombination will be radiatively recombined, and hence an output power of the light emitting device will be enhanced (Applied Physics Letters, Vol. 87, 151119, 2005).

Such an increase of the spontaneous emission rate by the cavity is called Purcell effect, which is expected to be applied to light emitting devices as a method of enhancing light emission which is different from enhancement of fluorescence through stimulated emission.

Now, referring to FIGS. 10A to 10C, a structure of the light emitting device including a cavity of the photonic crystal in a conventional example is described.

FIG. 10A is a cross-sectional view of the light emitting device. A light emitting device 1001 includes a photonic crystal layer 1002, an active layer 1003 inside the photonic crystal layer 1002, a cladding layer 1004, and an electrode 1005.

The cladding layer 1004 is made of a material having a refractive index lower than an effective refractive index (mean value of the refractive index) of the photonic crystal layer so as to confine light in the photonic crystal layer 1002.

Both the cladding layer 1004 and the photonic crystal layer 1002 are electrically conductive and transport carriers injected from the electrode 1005 to the active layer 1003.

FIG. 10B is a top view of the photonic crystal layer. The photonic crystal layer has a structure 1006 different from a periodic structure of the photonic crystal (hereinafter, this structure is referred to as a defect).

Light emitted in this defect is confined by the periodic structure of the photonic crystal in the in-plane direction.

In the space in which light is confined by the cladding layer and the defect (referred to as a defect cavity), a very strong electric field is generated, and coupling between the electric field and the active layer placed in the space is enhanced. As a result, the spontaneous emission rate of the active layer is increased.

FIG. 10C shows a spectrum of light emitted from the light emitting device 1001 (solid line).

The broken line of FIG. 10C indicates a photoluminescence spectrum of the light emitting device without a hole 1007 constituting the photonic crystal.

When the broken line of FIG. 10C is compared to the solid line thereof, it is understood that, in a case where the light emitting device has the defect cavity, there is a sharp output peak at the same frequency as a resonance frequency ω₀ of the defect cavity.

This output peak is generated through enhancement of the spontaneous emission rate by the defect cavity.

Enhancement of the light emission by increasing the spontaneous emission rate does not need population inversion of the carriers unlike in a laser using stimulated emission. In addition, there is no current threshold value with an increase of the spontaneous emission rate unlike in a laser.

FIG. 11 is a top view of the photonic crystal in which defect cavities illustrated in FIG. 10B are arranged in array (hereinafter, defect cavities arranged in array are referred to as a defect cavity array).

Through use of the photonic crystal in which defect cavities are arranged in array as illustrated in FIG. 11, the light emission enhancement effect can be obtained in a large area.

However, the above-mentioned photonic crystal of the conventional example illustrated in FIG. 11, in which defect cavities are arranged, has a problem in that electromagnetic fields of close defect cavities interact with each other so that the resonance frequencies of the defect cavities vary, and hence the light emission enhancement effect is lowered.

Now, referring to FIGS. 12A and 12B, this problem is described. FIG. 12A illustrates the defect cavities arranged in an x direction to be a one-dimensional array.

The one-dimensional array of defect cavities exchanges electromagnetic field energy among close defect cavities.

As a result, a resonance mode of the electromagnetic field of the defect cavity is expressed as a Bloch function propagating in the x direction at a wavenumber K.

As an approximation, when only energy exchange between the closest defect cavities is considered, the resonance frequency of the resonance mode is expressed by the following expression (1).

$${ω}_{K} = Ω [ 1 - \frac{Δα}{2} + κ cos ( KR ) ] \qquad Expression ( 1 )$$

In the expression (1), Ω represents a resonance frequency of the defect cavity that is not arranged in array as illustrated in FIG. 10B, and R represents a distance between the closest defect cavities of FIG. 12A.

If N defect cavities constitute the one-dimensional array, the wavenumber K is any one of values expressed by K=2πn/RN (n=1, 2, . . . N).

In the expression (1), the second term indicates a shift of the resonance frequency due to the energy exchange between the defect cavities, and the third term indicates variation in the resonance frequency depending on the wavenumber K.

The shift of the resonance frequency of the second term can be corrected by adjusting a period of the photonic crystal (i.e. the distance between the closest cavities). Therefore, the second term is omitted in the following discussion.

A coefficient κ in the third term indicates an overlap integral of the electric field between the closest defect cavities, which is expressed by the following expression (2).

κ=∫(∈₀−∈)EⁿEⁿ⁻¹dr Expression (2)

In the expression (2), ∈₀ represents the distribution of a dielectric constant in the defect cavity that is not arranged in array as illustrated in FIG. 10B, and ∈ represents the distribution of a dielectric constant in the defect cavities that are arranged in array as illustrated in FIG. 12A.

In addition, Eⁿ and Eⁿ⁻¹ each represent electric fields of modes in neighboring n-th and (n−1)th defect cavities, where the modes are degenerated.

Herein, “modes are degenerated” means that the modes have the same resonance frequencies of defect cavities in a case where they are not arranged in array.

No exchange of the electromagnetic field energy is generated between modes of defect cavities that are not degenerated.

The κ expressed by the expression (2) indicates an intensity of the energy exchange between modes.

FIG. 12B illustrates an electric field of a dipole eigenstate (dipole mode) for neighboring defect cavities.

In FIG. 12B, dipole modes 1201 and 1202 oscillating in the x direction and dipole modes 1203 and 1204 oscillating in the y direction are illustrated.

The defect cavities are fourfold symmetric having mirror symmetry in the x direction and the y direction, and hence the dipole modes 1201 to 1204 are degenerated.

In this case, the energy exchange occurs between the modes, and because of symmetry of the dipole modes, κ of the dipole modes 1201 and 1202, which are oscillating in the same direction, and κ of the dipole modes 1203 and 1204, which are oscillating in the same direction, have a non-zero value.

A graph on the left side of FIG. 13 shows a photoluminescence spectrum of the active layer, and a graph on the right side of FIG. 13 shows resonance frequencies expressed by the expression (1) with various K values.

As shown in FIG. 13, when a value of the overlap integral κ of the electric field is increased, some resonance frequencies are not within an emission frequency band 1303 of the active layer. Herein, the emission frequency band refers to a frequency in a half value width of the photoluminescence spectrum.

Modes having the resonance frequencies that are not within the emission frequency band 1303 of the active layer (black dots on the right side of FIG. 13) have decreased coupling strength with the active layer and hardly contribute to enhancement of the photoluminescence.

The value of the overlap integral κ is increased when the distance R between the defect cavities is decreased. Hence, the number of the modes that do not contribute to the enhancement of the photoluminescence is increased when the defect cavities per unit area are increased by making cavities close to each other.

Therefore, the defect cavity array has a problem in that even if the number of the defect cavities is increased, resonance frequencies are varied by the exchange of the electromagnetic field energy between the defect cavities and thus the enhancement of the photoluminescence cannot be sufficiently obtained.

The problem in the one-dimensional defect cavity array is described above, but such a problem occurs similarly in a two-dimensional defect cavity array.

The mode in the two-dimensional defect cavity array is expressed by a Bloch function described as a wavenumber vector K.

In this case, κ determining the range of the varied resonance frequencies is defined by the expression (2) as the overlap integral of the fields of the closest defect cavities similarly to the one-dimensional array.

### SUMMARY OF THE INVENTION

In view of the above-mentioned problem, the present invention is directed to provide a light emitting device that can suppress variation in a resonance frequency of a mode even in a case where photonic crystal, in which defect cavities are arranged, is used, so that the light emission can be enhanced at high efficiency.

A light emitting device according to an exemplary embodiment of the present invention includes: an active layer; a photonic crystal layer including defects introduced therein, the defects disturbing periodicity of a refractive index distribution of photonic crystal; and a cladding layer having a refractive index lower than an effective refractive index of the photonic crystal layer, in which the defects of the photonic crystal layer constitute defect cavities. The photonic crystal layer has a structure in which the defect cavities are arranged. Each of the arranged defect cavities has a major axis and a minor axis having different axial lengths, and the major axes are directed in different directions between neighboring defect cavities.

According to the exemplary embodiment of the present invention, it is possible to achieve the light emitting device that can suppress the variation in the resonance frequency of the mode so that the light emission can be enhanced at high efficiency even in the case where the photonic crystal, in which defect cavities are arranged, is used.

Further features of the present invention will become apparent from the following description of exemplary embodiments with reference to the attached drawings.

### BRIEF DESCRIPTION OF THE DRAWINGS

FIG. 1A is a diagram illustrating a structural example of a light emitting device according to a first embodiment of the present invention.

FIG. 1B is a diagram illustrating a structural example of the light emitting device according to the first embodiment of the present invention.

FIG. 2A is a diagram illustrating neighboring defect cavities and dipole modes thereof in the first embodiment of the present invention.

FIG. 2B is a diagram illustrating neighboring defect cavities and dipole modes thereof in the first embodiment of the present invention.

FIG. 3 is graphs showing a photoluminescence spectrum of an active layer and variation in a resonance frequency of a defect cavity array according to the first embodiment of the present invention.

FIG. 4 is a top view of a photonic crystal layer forming a light emitting device according to a second embodiment of the present invention.

FIG. 5A is a diagram illustrating neighboring defect cavities and dipole modes thereof in the second embodiment of the present invention.

FIG. 5B is a diagram illustrating neighboring defect cavities and dipole modes thereof in the second embodiment of the present invention.

FIG. 6 is a top view of a photonic crystal layer forming a light emitting device according to a third embodiment of the present invention.

FIG. 7A is a diagram illustrating neighboring defect cavities and dipole modes thereof in the third embodiment of the present invention.

FIG. 7B is a diagram illustrating neighboring defect cavities and dipole modes thereof in the third embodiment of the present invention.

FIG. 8A is a diagram illustrating a defect cavity having a major axis and a minor axis formed in square lattice photonic crystal according to a fourth embodiment of the present invention.

FIG. 8B is a diagram illustrating a defect cavity having a major axis and a minor axis formed in square lattice photonic crystal according to the fourth embodiment of the present invention.

FIG. 8C is a diagram illustrating a defect cavity having a major axis and a minor axis formed in square lattice photonic crystal according to the fourth embodiment of the present invention.

FIG. 8D is a diagram illustrating a defect cavity having a major axis and a minor axis formed in square lattice photonic crystal according to the fourth embodiment of the present invention.

FIG. 8E is a diagram illustrating a defect cavity having a major axis and a minor axis formed in square lattice photonic crystal according to the fourth embodiment of the present invention.

FIG. 9A is a diagram illustrating a defect cavity having a major axis and a minor axis formed in triangular lattice photonic crystal according to the fourth embodiment of the present invention.

FIG. 9B is a diagram illustrating a defect cavity having a major axis and a minor axis formed in triangular lattice photonic crystal according to the fourth embodiment of the present invention.

FIG. 9C is a diagram illustrating a defect cavity having a major axis and a minor axis formed in triangular lattice photonic crystal according to the fourth embodiment of the present invention.

FIG. 9D is a diagram illustrating a defect cavity having a major axis and a minor axis formed in triangular lattice photonic crystal according to the fourth embodiment of the present invention.

FIG. 9E is a diagram illustrating a defect cavity having a major axis and a minor axis formed in triangular lattice photonic crystal according to the fourth embodiment of the present invention.

FIG. 10A is a cross-sectional view of a light emitting device formed by a related art.

FIG. 10B is a top view of photonic crystal layer formed by the related art.

FIG. 10C is a graph showing an output of the light emitting device formed by the related art.

FIG. 11 is a top view of the photonic crystal layer formed by the related art.

FIG. 12A is a top view of a one-dimensional defect cavity array formed by the related art.

FIG. 12B is a diagram illustrating dipole modes of the one-dimensional defect cavity array formed by the related art.

FIG. 13 is graphs showing a photoluminescence spectrum of an active layer and resonance frequencies in the defect cavity array formed by the related art.

### DESCRIPTION OF THE EMBODIMENTS

Hereinafter, a structural example of a light emitting device according to embodiments of the present invention is described with reference to the attached drawings.

### First Embodiment

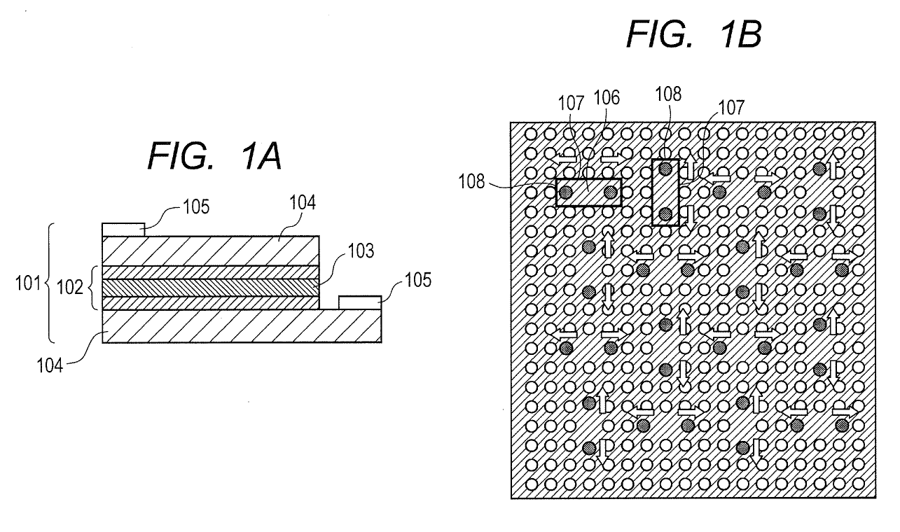

Now, as a first embodiment of the present invention, a structural example of the light emitting device is described, with reference to FIGS. 1A, 1B, 2A, 2B, and 3.

A light emitting device of this embodiment includes: an active layer; a photonic crystal layer including defects introduced therein, the defects disturbing periodicity of a refractive index distribution of photonic crystal; and a cladding layer having a refractive index lower than an effective refractive index of the photonic crystal layer. Further, the defects in the photonic crystal layer are arranged to be a defect cavity array.

A specific structure of the light emitting device is illustrated in a cross sectional view of the light emitting device of FIG. 1A.

As illustrated in FIG. 1A, a light emitting device 101 of this embodiment includes a photonic crystal layer 102 having a periodic refractive index distribution, an active layer 103, a cladding layer 104 for confining light in the photonic crystal layer, and an electrode 105 for injecting carriers into the light emitting device.

FIG. 1B is a top view of the photonic crystal layer.

As illustrated in FIG. 1B, the photonic crystal layer is provided with defect cavities arranged, in array, in tetragonal lattice.

The defect cavities constituting the defect cavity array of FIG. 1B each include a region 107 from which holes of the photonic crystal are removed, and a pair of holes are shifted in arrow directions of FIG. 1B (black dots of FIG. 1B).

A region enclosed by the solid line of FIG. 1B is a region defined by connecting tangent lines of holes (white circles) intrinsic to the photonic crystal. The region indicates a defect cavity 106.

The defect cavity 106 has a major axis 107 in the direction in which the hole is shifted and a minor axis 108 in the direction perpendicular to the major axis.

Between neighboring defect cavities, namely between closest defect cavities, pairs of holes (black dots) are shifted in different directions, and the major axes of the defect cavities are directed to the directions different by 90 degrees.

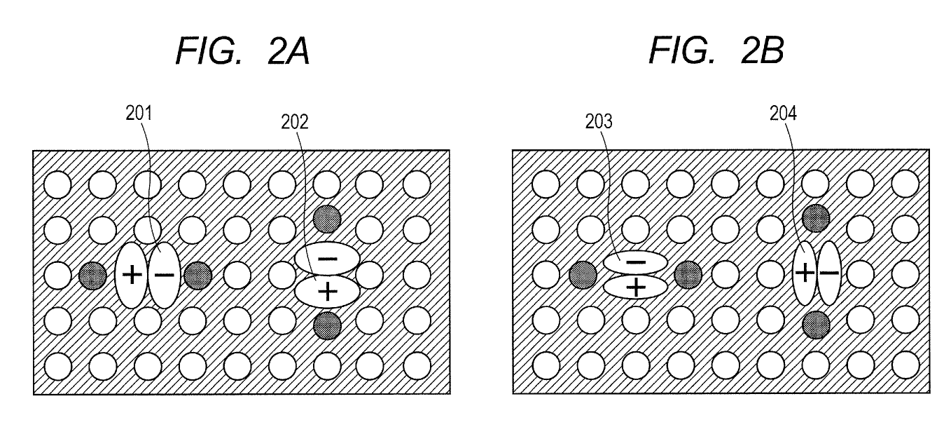

FIGS. 2A and 2B illustrate a top view of the neighboring defect cavities and electric fields of dipole modes generated in the defect cavities.

The holes indicated by the black dots are shifted, and hence a cross section of the defect cavity in the x direction is not identical to a cross section of the defect cavity in the y direction.

Therefore, dipole modes 201 and 202 of FIG. 2A and dipole modes 203 and 204 of FIG. 2B are not degenerated, and hence an exchange of the electromagnetic field energy is not generated between them.

On the other hand, in FIGS. 2A and 2B, close dipole modes 201 and 202 illustrated in FIG. 2A, and close dipole modes 203 and 204 illustrated in FIG. 2B are degenerated.

However, between the neighboring cavities, the oscillation directions are different by 90 degrees, and the overlap integral K expressed by the expression (2) can be substantially zero.

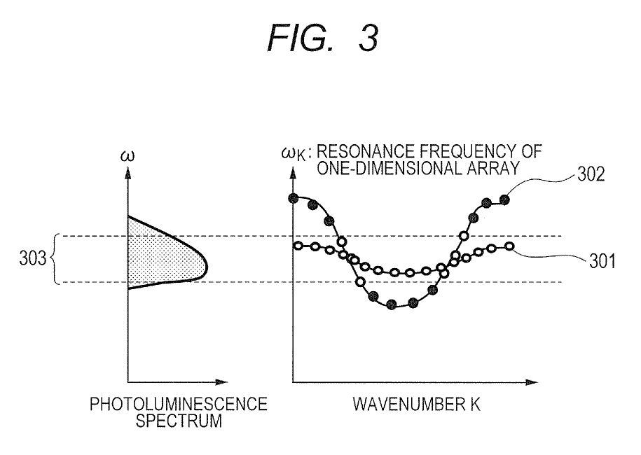

A graph on the left side of FIG. 3 shows a photoluminescence spectrum of the active layer. As described above, the emission frequency band of the active layer is within the half value width of this photoluminescence spectrum.

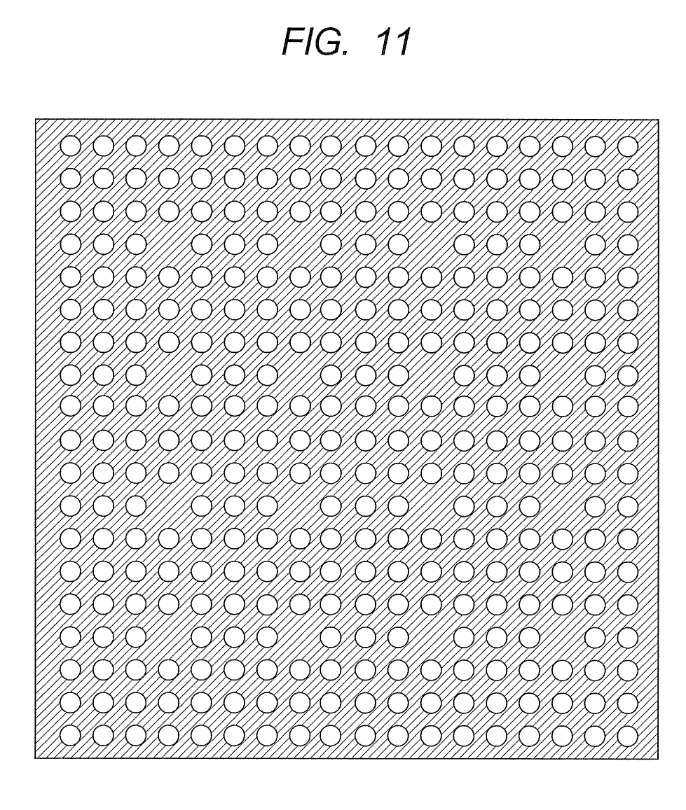

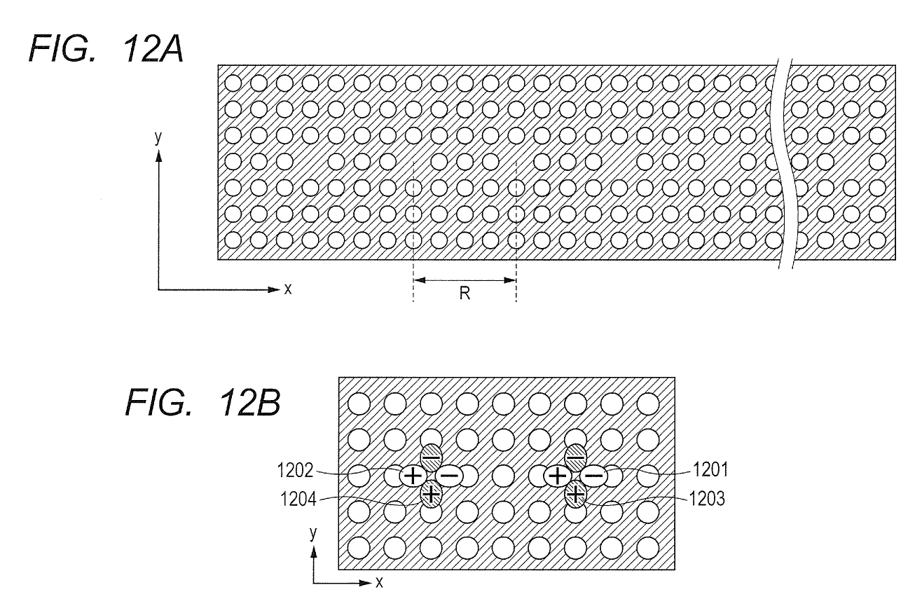

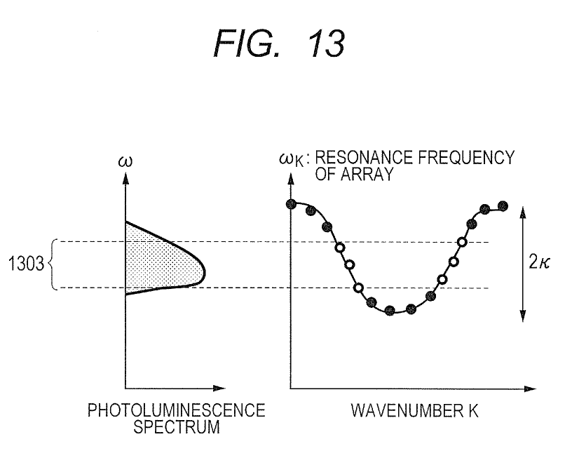

A graph on the right side of FIG. 3 shows resonance frequencies 301 of the defect cavity array of FIG. 1B and resonance frequencies 302 of the conventional defect cavity array illustrated in FIG. 11.

Referring to FIG. 3, it is understood that, in comparison with the conventional defect cavity array, the defect cavity array of this embodiment has more suppressed variation in the resonance frequency.

In other words, the conventional defect cavity array has modes that do not contribute to enhancement of the light emission (black dots on the right side of FIG. 3), but in this embodiment, resonance frequencies of all modes are within an emission frequency band 303 of the active layer and all modes contribute to the enhancement of the light emission.

As a result, the light emitting device illustrated in FIGS. 1A and 1B has a larger enhancement effect of the light emission and becomes a light emitting device having higher luminance than that of the conventional example.

### Second Embodiment

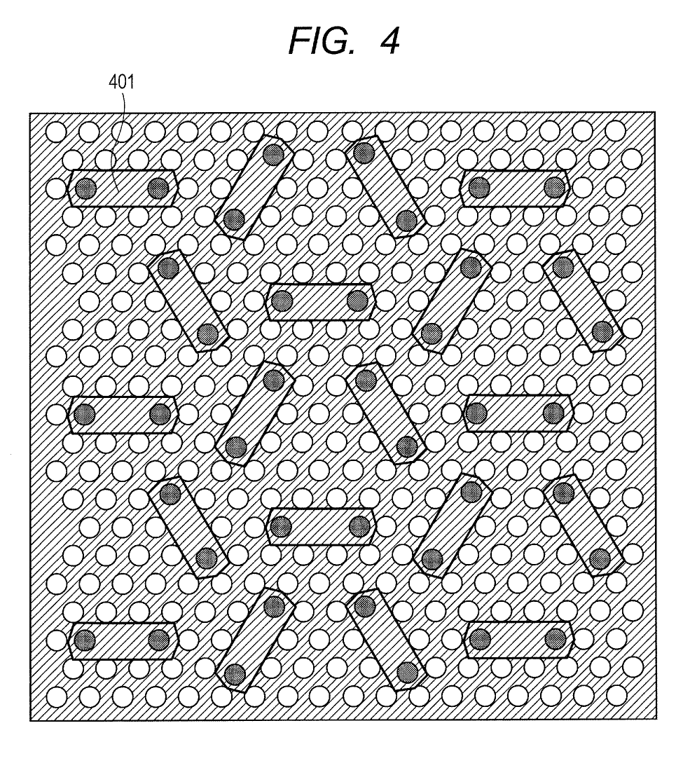

As a second embodiment of the present invention, a structural example different from the first embodiment is described with reference to FIGS. 4, 5A, 5B, and 6.

FIG. 4 is a top view of a triangular lattice photonic crystal layer in a light emitting device of this embodiment.

In the photonic crystal layer, the defect cavities are arranged in triangular lattice so as to form a defect cavity array.

The defect cavities each include a region from which holes are removed, and a pair of opposite holes are shifted (black dots of FIG. 4).

A region enclosed by tangent lines of holes (white circles) intrinsic to the photonic crystal indicates a defect cavity 401. The defect cavity has a major axis in the direction in which the hole is shifted and a minor axis in the direction perpendicular to the major axis.

In this embodiment, the major axial direction of the defect cavity is different between the closest defects, namely between the neighboring defect cavities, by 60 degrees.

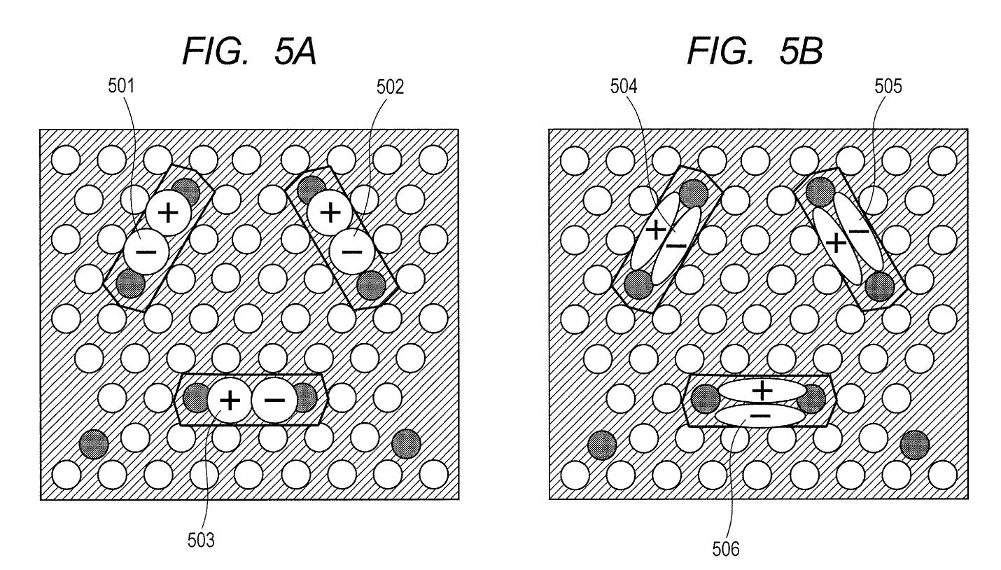

FIGS. 5A and 5B illustrate neighboring defect cavities and dipole modes thereof.

Dipole modes 501, 502, and 503 of FIG. 5A and dipole modes 504, 505, and 506 of FIG. 5B are not degenerated. Therefore, no exchange of the electromagnetic field energy occurs between them.

On the other hand, the close dipole modes 501, 502, and 503 illustrated in FIG. 5A are degenerated.

However, the oscillation directions are different by 60 degrees between the neighboring defect cavities, and hence the overlap integral κ is smaller than that in the case where the dipole modes oscillate in the same direction.

Similarly, the close dipole modes 504, 505, and 506 illustrated in FIG. 5B are degenerated, but the overlap integral κ is small because the oscillation directions are different by 60 degrees.

In other words, in the defect cavity array illustrated in FIG. 4, the variation in the resonance frequency is suppressed. Therefore, the light emitting device including the defect cavity array illustrated in FIG. 4 becomes a light emitting device having high luminance in which the light emission is effectively enhanced.

### Third Embodiment

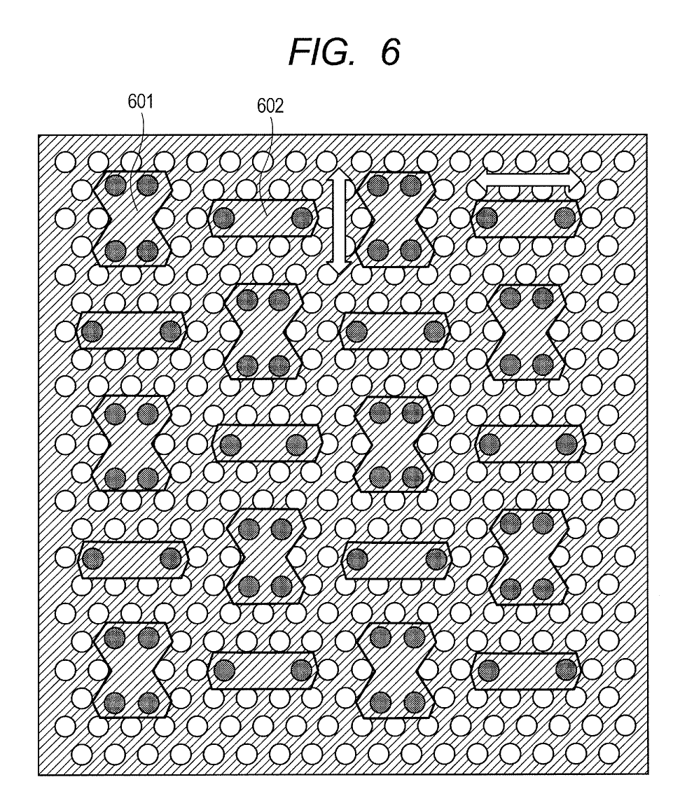

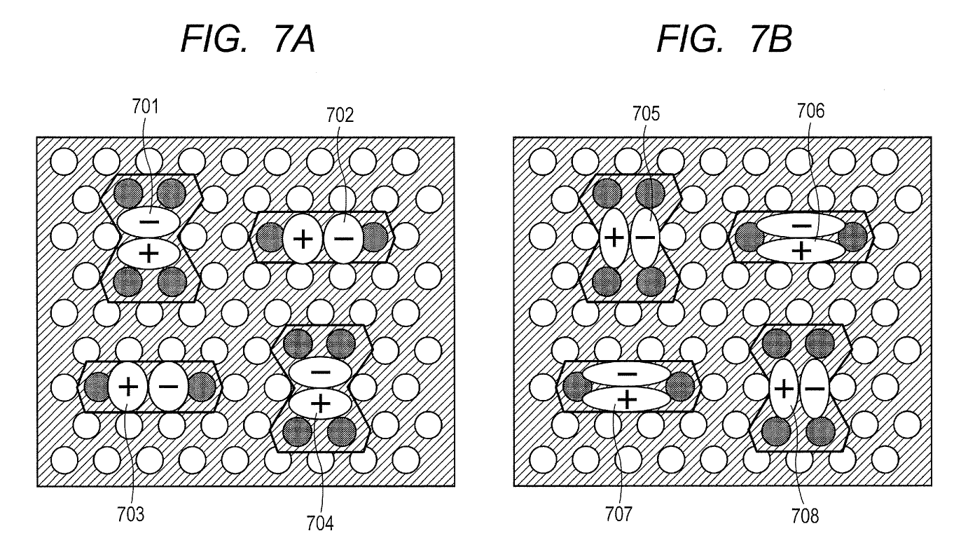

As a third embodiment of the present invention, a structural example different from the above-mentioned first and second embodiments is described with reference to FIGS. 6, 7A, and 7B.

FIG. 6 is a top view of a photonic crystal layer in a light emitting device of this embodiment.

In the photonic crystal layer, the defect cavities are arranged in rectangular lattice so as to form a defect cavity array.

The defect cavities each include a region from which holes are removed, and a pair of opposite holes or two pairs of opposite holes (black dots of FIG. 6) are shifted. In this embodiment, those holes are shifted toward the outside of the defect cavity.

Regions enclosed by tangent lines of holes (white circles) intrinsic to the photonic crystal respectively indicate defect cavities 601 and 602.

The defect cavity has a major axis in the direction in which the hole is shifted and a minor axis in the direction perpendicular to the major axis (the directions are indicated by arrows in FIG. 6). In this embodiment, the major axial direction of the defect cavity is different between the closest defects by 90 degrees.

FIGS. 7A and 7B illustrate defect cavities arranged in rectangular lattice and dipole modes thereof.

Dipole modes 701 to 704 illustrated in FIG. 7A and dipole modes 705 to 708 illustrated in FIG. 7B are not degenerated.

Therefore, no exchange of the electromagnetic field energy occurs between the dipole modes illustrated in FIG. 7A and the dipole modes illustrated in FIG. 7B.

On the other hand, the close dipole modes 701 to 704 illustrated in FIG. 7A can be degenerated depending on the shifts of the holes indicated by the black dots. However, the oscillation directions are different by 90 degrees between the closest defect cavities, and hence the overlap integral κ can be substantially zero.

Similarly, the close dipole modes 705 to 708 illustrated in FIG. 7B are also degenerated, but the overlap integral κ can be substantially zero because the oscillation directions are different by 90 degrees. As a result, the defect cavity array illustrated in FIG. 6 has suppressed variation in the resonance frequency, and the light emitting device including the defect cavity array becomes a light emitting device having high luminance.

In general, the overlap integral of the dipole mode in which the oscillation directions are different by degrees as illustrated in FIG. 6 is smaller than the overlap integral in the case where the oscillation directions are different by 60 degrees as illustrated in FIG. 4.

Therefore, in the triangular lattice photonic crystal, FIG. 6 illustrates a more desirable embodiment.

### Fourth Embodiment

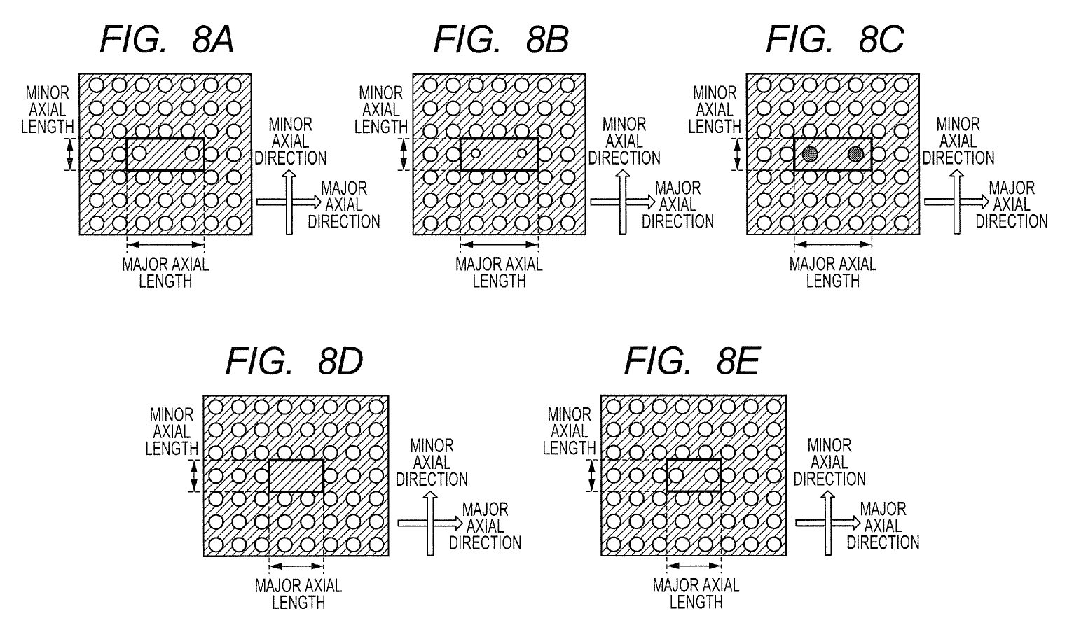

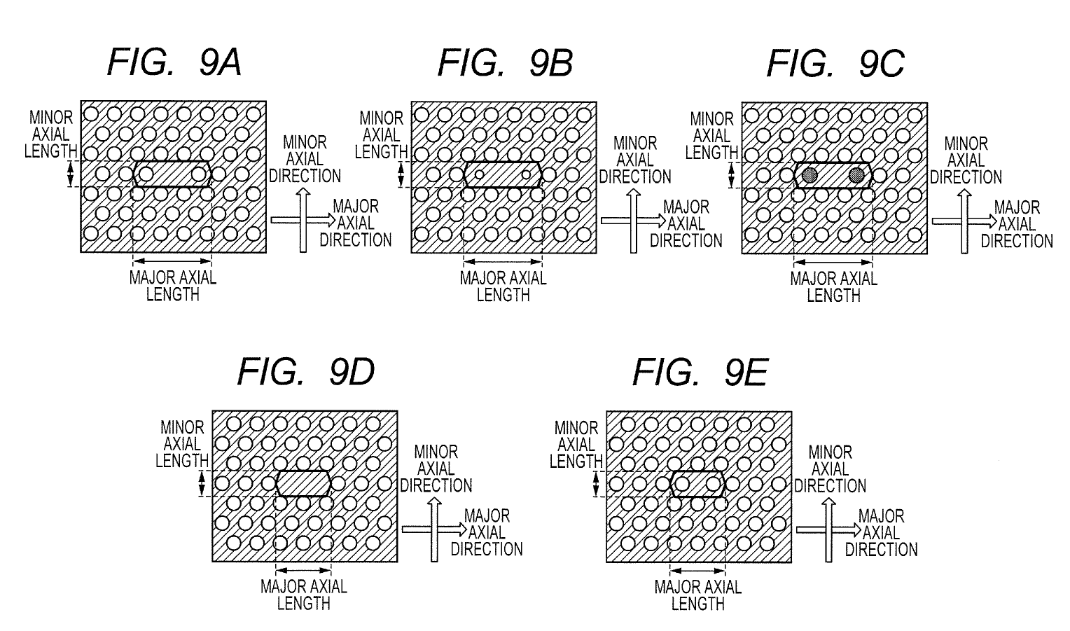

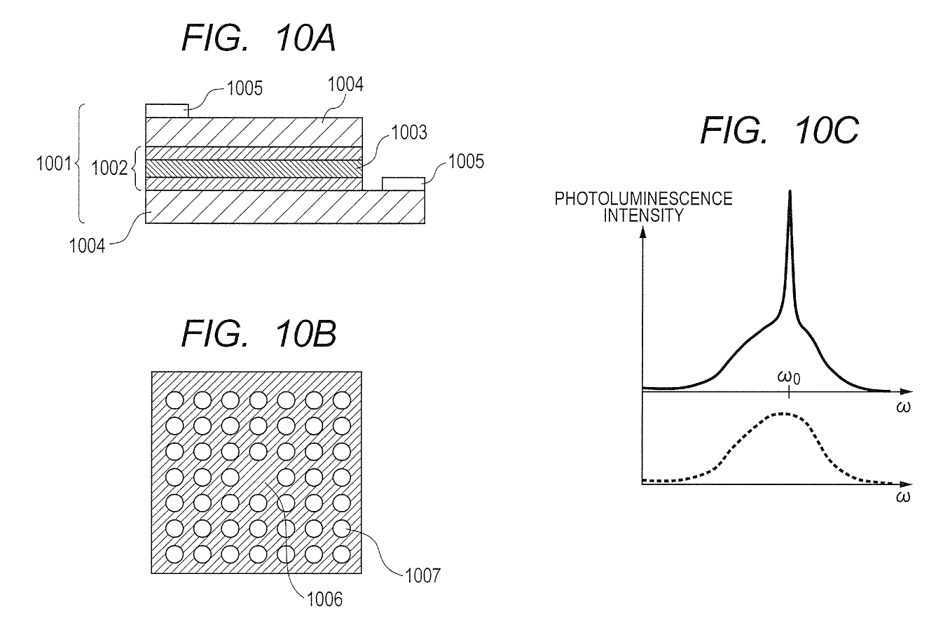

As a fourth embodiment of the present invention, various structural examples of defect cavities are described with reference to FIGS. 8A to 8E, and 9A to 9E.

FIGS. 8A and 9A illustrate defect cavities formed by shifting the holes as described above in the first to third embodiments.

The region of the defect cavity can be seen by connecting tangent lines of the holes intrinsic to the photonic crystal (the region enclosed by the straight lines of FIGS. 8A to 8E, and 9A to 9E).

In FIGS. 8A and 9A, the direction in which the hole is shifted is the major axial direction, and the direction perpendicular to the major axial direction is the minor axial direction.

FIGS. 8B and 9B illustrate the defect cavities formed by changing diameters of a pair of opposite holes. In this case, the direction connecting the holes whose diameters are changed is the major axial direction.

In addition, FIGS. 8C and 9C illustrate the defect cavities formed by filling a pair of opposite holes with a material different from that of the photonic crystal layer. In this case, the direction connecting the holes that are filled with the material different from that of the photonic crystal layer is the major axial direction.

FIGS. 8D and 9D illustrate the defect cavities formed by removing two neighboring holes. In this case, the direction in which the removed holes are aligned is the major axial direction. FIGS. 8E and 9E illustrate the defect cavities formed by shifting the close holes without removing the holes. In this case, the direction of shifting the holes is the major axial direction.

In any case, the defect cavities are mirror symmetric with respect to the major axial direction and with respect to the minor axial direction perpendicular to the major axial direction, and a major axial length is different from a minor axial length.

Therefore, in the defect cavities illustrated in FIGS. 8A to 8E and 9A to 9E, the dipole mode oscillating in the major axial direction and the dipole mode oscillating in the minor axial direction are not degenerated.

In addition, those defect cavities illustrated in FIGS. 8A to 8E and 9A to 9E may be arranged in array so that the major axial directions are different between the closest defect cavities, the overlap integral κ can be small also between the degenerated dipole modes.

In addition, the shape of the defect cavity of the present invention is not limited to the shapes illustrated in FIGS. 8A to 8E and 9A to 9E.

For instance, the diameter of the pair of holes illustrated in FIGS. 8B and 9B may be increased.

In addition, in FIGS. 8A, 8E, 9A, and 9E, the hole may be shifted in the opposite direction to that of FIGS. 8A, 8E, 9A, and 9E. In addition, in FIGS. 8A to 8D and 9A to 9D, two or more holes may be removed.

According to the structure of the present invention described above, the value of the overlap integral κ is decreased, and the variation in resonance frequencies can be suppressed. As a result, the number of modes having the resonant frequencies within the emission frequency band of the active layer is decreased, and hence the luminance of the light emitting device can be efficiently improved.

The improvement of the luminance of the light emitting device according to the present invention is attributed to enhancement of the spontaneous emission rate by increasing coupling between the electric field in the defect cavity and the active layer.

Therefore, a structure according to the present invention can produce a larger effect in a device with an active layer having intrinsically a small spontaneous emission rate, such as silicon nanoparticles or silicon quantum wells.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-126780, filed Jun. 6, 2011, which is hereby incorporated by reference herein in its entirety.

What is claimed is:

1. A light emitting device, comprising:
an active layer;
a photonic crystal layer including defects, as defect cavities, for disturbing periodicity of a refractive index distribution thereof; and
a cladding layer having a refractive index lower than an effective refractive index of the photonic crystal layer, wherein
the photonic crystal layer includes the defect cavities arranged therein; and
each of the defect cavities has a major axis and a minor axis having different axial lengths, and the major axes are directed in different directions between neighboring defect cavities.

2. The light emitting device according to claim 1, wherein the major axes are directed in directions different by 90 degrees between the neighboring defect cavities.

3. The light emitting device according to claim 1, wherein the major axes are directed in directions different by 60 degrees between the neighboring defect cavities.

4. The light emitting device according to claim 1, wherein the defect cavities are arranged in rectangular lattice.

5. The light emitting device according to claim 1, wherein the defect cavities are arranged in tetragonal lattice.

6. The light emitting device according to claim 1, wherein the each of the defect cavities is formed by being filled with a material different from a material of the photonic crystal layer.

7. The light emitting device according to claim 1, wherein the each of the defect cavities has a resonance frequency of a dipole mode generated in the each of the defect cavities, the resonance frequency being within a half value width of a photoluminescence spectrum of the active layer.

8. The light emitting device according to claim 1, wherein the active layer includes one of a silicon nanoparticle and a silicon quantum well.
